(19) United States
(12) Patent Application Publication
(10) Pub. No.: US 2006/0280019 A1
(43) Pub. Date: Dec. 14, 2006

(54) Error based supply regulation

(76) Inventors: Edward A. Burton, Hillsboro, OR (US); Anant Deval, Beaverton, OR (US); Nivruti Rai, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/151,821

(22) Filed: Jun. 13, 2005

(51) Int. Cl. G11C 5/14

(52) U.S. Cl. 365/226

(57) ABSTRACT

In some embodiments, an error based supply regulation scheme is provided where error information from a cache is monitored, and the supply level supplying a CPU associated with the cache is controlled based on the error information. Other embodiments are disclosed herein.

### BACKGROUND

With many integrated circuit (IC) chips such as microprocessor chips, a minimum operating supply (e.g., VCCₘᵢₙ) can be a limiter in the drive for lower powered operation. Pushing the minimum operational supply lower can result in a significant power reduction. In many chips, lowering the minimum supply parameter can also increase the probability of encountering an uncorrectable error, so a balance is normally sought. The minimum supply parameter for many chips often will steadily increase over time. Thus, a large guardband (i.e., tolerance for degradation over time) on the minimum supply parameter may be used. Unfortunately, the use of such a guardband can force all parts (e.g., in a lot) to consume more power than necessary.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram of a microprocessor including an error based supply regulation circuit according to some embodiments of the invention.

FIG. 2 is a flow diagram showing a routine to perform error based supply regulation according to some embodiments of the circuit of FIG. 1.

FIG. 3 is a block diagram of a microprocessor including another error based supply regulation circuit according to some embodiments of the invention.

FIG. 4 is a flow diagram showing a routine to perform error based supply regulation according to some embodiments of the circuit of FIG. 3.

FIG. 5 is a block diagram of a content addressable memory to implement an error log according to some embodiments of the invention.

FIG. 6 is a block diagram of a computer system with an error based supply regulation circuit in accordance with the circuit of FIG. 1.

### DETAILED DESCRIPTION

In some embodiments, error based supply regulation may be used to regulate the supply level (e.g., voltage, VCC, current, power) for a circuit or group of circuits in a chip. For example, a supply voltage for a central processing unit (CPU) may be controlled based on monitored error information from cache memory associated with the CPU. The cache may be a good candidate for error monitoring since it is typically the first circuit to fail as the VCC is reduced. In addition, with many commonly-used CPU devices, a cache may already have error information readily available for monitoring.

Cache architectures may have error detection as well as error correction circuitry. (Note that the term cache generally refers to a random access memory (RAM) structure used in a processor chip. It could comprise dynamic or static RAM implemented with any suitable cell structure such as so-called 1T, 2T, 4T, or 6T cells (to mention just a few.) Single bit, dual bit, and other error correction schemes are generally known. With a single bit scheme, one erroneous bit per line (BPL) is correctable and two erroneous BPL are detectable. Likewise, in a dual bit scheme, two BPL are correctable and 3 BPL are detectable. Cache systems employing such schemes can generally provide error information, such as the number of corrected bits, actual corrected bit-locations (cells), and/or the number of detected bit errors.

In cache memory systems, single bits per cache line typically begin failing long before multiple bits per cache line. In fact, the errors are typically largely random. Thus, for example, if the supply level is lowered until one in a thousand cache lines have a single bit error, it is reasonably likely that around one in a million lines would have two bad bits (or cells). Since single bit errors (per cache line) are typically correctable (e.g., in systems with single bit correction or higher), the voltage can safely be lowered below the point where single bits per line begin to fail. In fact, the probability of encountering an uncorrectable multi-bit error can be made arbitrarily small by holding the voltage just high enough to limit the total number of single bit corrections residing in the cache to some predetermined limit.

Either static or dynamic supplies may be controlled. (A static supply is a supply not otherwise varied during operation, while a dynamic supply is a supply that may be changed during operation, e.g., depending on operational mode such as to enhance operational efficiency.) With either case, the supply may be dynamically adjusted (in addition to the supply already being dynamically adjusted for dynamic supplies) in response to error information, e.g., to enhance operational efficiency. It could also be used to change a minimum allowed supply level (commonly referred to as a “guardband”) in response to changes in errors over time in order to have a lower guardband—at least at the beginning of a chip's life cycle.

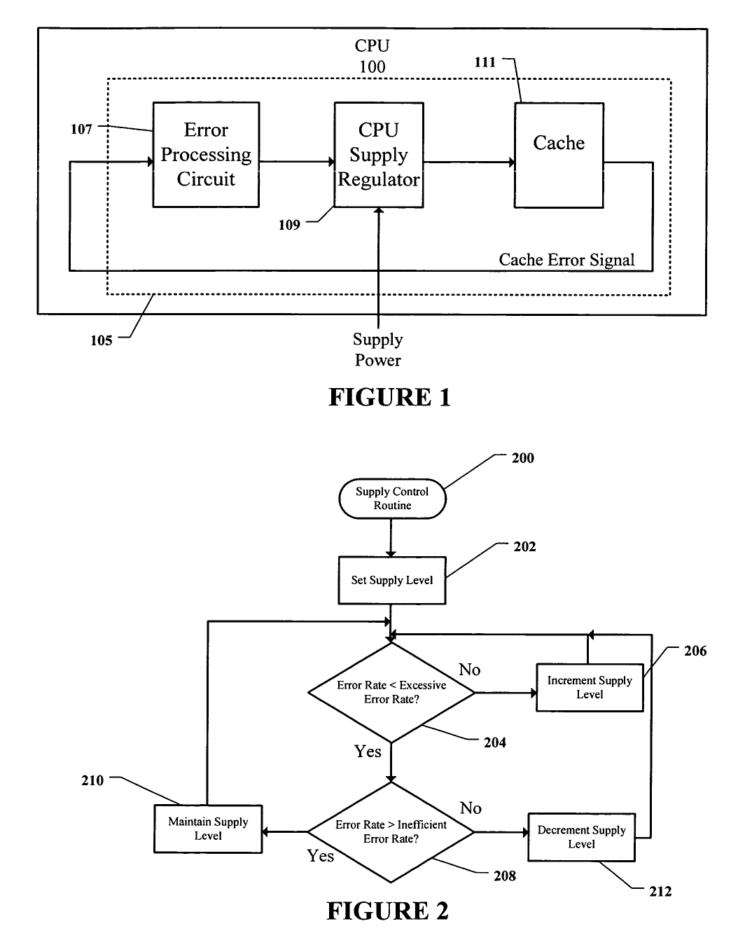

With reference to FIG. 1, a circuit 105 in a CPU chip 100 is shown. Supply regulator circuit 105 regulates a supply voltage for the CPU based on error feedback information from a cache associated with the CPU. It generally comprises an error processing circuit 107, a CPU supply regulator 109, and a cache memory 111. The CPU supply regulator 109 is coupled between the error processing circuit 107 and cache 111 to provide one or more regulated supply voltages (VCC), with at least one used to supply the cache 111. The CPU supply regulator 109 generates the supply voltage (e.g., from an externally supplied power signal) and controls the voltage supplied to the cache based on an error signal coupled from the cache 111 to the error processing circuit 107. An error processing circuit may be any suitable circuit or circuit combination for controlling a supply level based on received error feedback information. It could comprise application specific circuitry (e.g., static logic, combinational logic, and/or analog circuits), and/or it could be implemented with an already available circuit such as a micro-controller.

With reference to FIG. 2, in some embodiments, the error processing circuit 107 may perform a supply control routine 200 based on bit error rate information. Initially, at 202, it sets a supply level. This initial supply level could, for example, be hard-wired or retrieved from nonvolatile memory such as a one time programmable memory, flash memory, firmware, or the like. Furthermore, it could be a worst case value for all chips in a manufactured lot or it could be a specific value for a specific chip.

Next, at decision step 204, it determines if the error rate (in the error signal from cache 111) is less than an excessive amount. For example, in a single-bit error correction scheme, an excessive rate might be a rate greater than one out of every thousand bits. (Since a single bit per line could be corrected, the likelihood of having more than one bit per line fail with this scheme would be on the order of one out of one million, an acceptable risk in some systems.) If the monitored error rate is equal or greater than the excessive amount, then at 206, the supply voltage would be incremented, e.g., by a predefined amount, and the routine would loop back to decision step 204.

On the other hand, if at step 204, it was determined that the error rate was not excessive, then it proceeds to decision step 208 and determines whether the error rate is greater than an insufficient rate. (This decision step is optional. It allows for the supply voltage level to be dropped even further for more efficient power consumption if the error rate is sufficiently small, i.e., it is insufficiently high for efficient operation.) At 212, if the error rate was in fact less than the insufficient rate, then the supply voltage level may be decremented. From here, the routine loops back to decision step 204 and proceeds as discussed. It can thus be seen that decision steps 204 and 208 define a range of error rate (i.e., insufficient rate<error rate<excessive rate) for operation where the supply level is neither incremented nor decremented. At step 208, if the error rate was greater than the insufficient rate value, then the routine would proceed to 210, and the supply voltage level would be maintained. From here, the routine loops back to decision step 204 and proceeds as described.

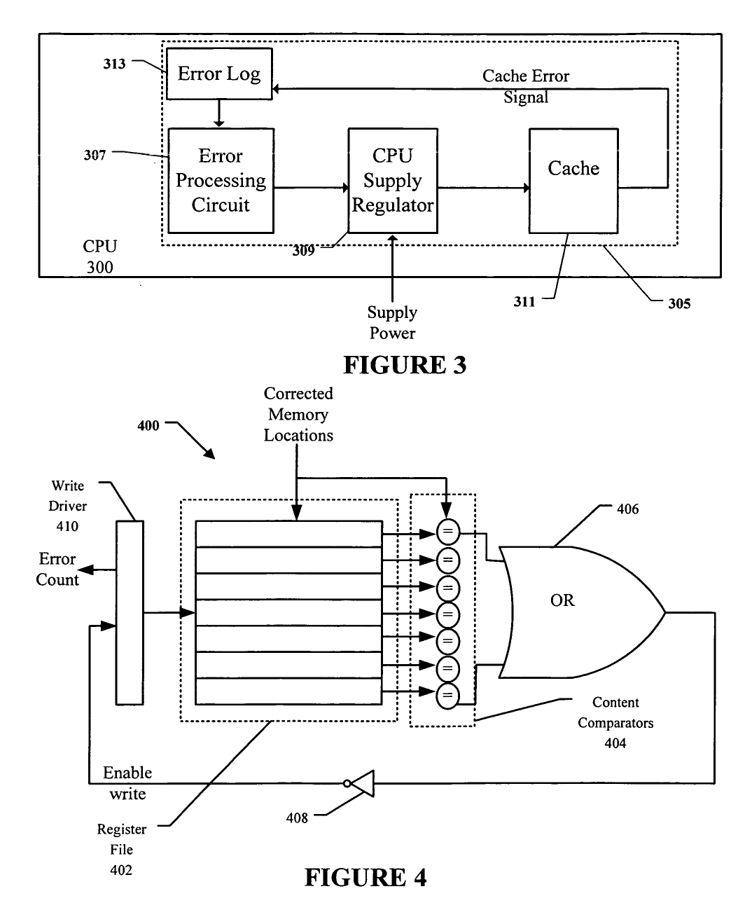

Other routines and/or error parameters (besides rate for example) could be implemented and monitored to control the supply level. Error rate is an efficient error signal parameter because in many systems, it may already be available or at least be generated with relatively little effort. Error rate monitoring works especially well in cache systems where the corrected bits are actually corrected in the memory array cell (as well as in the data provided out of the memory array). Otherwise, for example, if the same bit is being accessed, a high error rate may be perceived but not necessarily be the result of an insufficient supply level but instead the result of a repeatedly accessed defective cell. In many systems, this may be tolerable, but in others, different approaches may be used. A different approach is described below with respect to the embodiments of FIG. 3 to 5.

FIG. 3 shows a supply level regulator circuit 305 in a CPU 300 according to some other embodiments of the invention. with the depicted circuit 305, CPU supply voltage is controlled based on an error signal from CPU cache. However, rather than controlling the supply voltage based on a blind error rate signal (cache error incidence without taking cell location into account), it is controlled instead based on the number of unique, corrected memory locations.

The supply regulator circuit 305 generally comprises an error processing circuit 307, a CPU supply regulator 309, a cache 311, and an error log 313. The CPU supply regulator 309 is coupled between the error processing circuit 307 and cache 311 to provide one or more regulated supply voltages (VCC), with at least one used to supply the cache 311. The error log 313 is coupled to the cache 311 to receive from it error information from a cache error signal and to the error processing circuit 307 to provide it with error information used to control the supply voltage. The CPU supply regulator 309 generates the supply voltage from a power signal (e.g., externally supplied power) and controls the voltage supplied to the cache based on the error information provided to it from the error log 313.

The error log may comprise any suitable circuit (or circuit combination) to receive cache cell error information (e.g., location of corrected cells) and track the number of unique cells that have been corrected for a given session. For example, it could comprise an application specific circuit (e.g., a finite state machine) or it could be implemented with circuitry (a micro-controller) already included in a chip.

With reference to FIG. 4, in some embodiments, it could be implemented with a content addressable memory (CAM) structure such as CAM 400. In the depicted embodiment, CAM 400 generally comprises a register file 402, content comparators 404, OR gate 406, inverter 408, and a write driver 410. In operation, the locations of corrected bits are received (e.g., from the cache 311) and provided to the register file 402. When a location (e.g., address) arrives, it is compared, via content comparators 404, with locations (if any) already stored in the register file 402. If it is the same as any of the already stored locations, then the OR gate 406 is asserted, which causes the inverter 408 to de-assert causing the write driver 410 not to add the location to register file 402. On the other hand, if the received location is not equal to any of the already stored locations, the OR gate 406 de-asserts causing the inverter 408 to assert and the write driver 410 to add the location to the register file 402. In some embodiments, the write driver comprises a counter (not shown), which maintains a running count of the unique locations. This count is provided to the error processing circuit 307 via the Error Count signal.

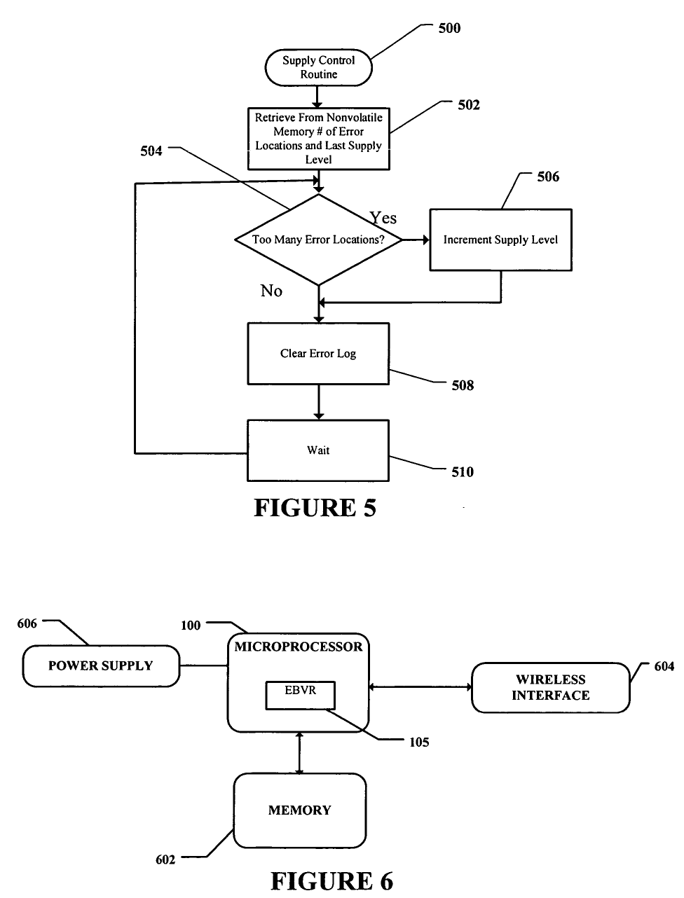

With reference to FIG. 5, a routine 500, which may be performed by the error processing circuit 307 to control CPU supply regulator 309, is depicted. Initially, at 502 (e.g., at start-up or CPU reset), the last supply level and count of unique bit-error locations are retrieved from nonvolatile memory. The supply level is controlled to be at this level, and at 504, the routine determines whether the unique bit-error location count from the previous session was excessive. If so, at 506, it increments the supply level and proceeds to 508 and clears the error log 313. Otherwise (if the number of unique locations was not excessive in the last session), then it proceeds directly from 504 to 508 and clears the error log 313. It then proceeds to 510 and waits for a predefined amount of time and then loops back to decision step 504.

While the routine 500 is running, error log 313 tracks and counts the number of unique bit-error locations. Thus, the time for waiting at 510 can be set to provide for an error logging that accurately indicates cache performance as it is affected by the supply voltage level. For example, this amount (in cooperation with the excessive level set for determination step 504) could be any suitable time, e.g., micro-seconds, seconds, minutes, hours, or otherwise. It may also depend on the type of error correction (e.g., single-bit, dual-bit, etc.) used. For example, the excessive level amount set for determination step 504 can be larger, and thus the CPU can be operated at a lower supply voltage level, when a dual-bit correction scheme is used. For example, at the point where one out of every 10,000 lines has a single bit error, only 1 line out of every 1,000,000,000,000 would have a 3-bit error (detectable, but not correctable), resulting in a reasonable safety margin for most cache systems.

Note that in the embodiments of FIGS. 1 and 2, the operating supply voltage was either increased or decreased depending on the error signal (error rate). However, with the described embodiment of FIG. 5, the minimum operating voltage is either increased or kept the same based on error information. (That is, it is not reduced.) In these embodiments, it may be done so at a relatively slow rate to target the lifetime degradation of a CPU and thereby allow for the minimum operating VCC to correspondingly increase over time. Accordingly, it allows for a dynamic rather than a fixed guardband, which enables it to operate more efficiently, at least in the beginning of a chip's life.

In other embodiments, circuit 305 could be operated more akin to routine 200 and allow for both decreasing and increasing the supply voltage based on the corrected cell count. In such embodiments, the wait time at step 510 of routine 500 may be set relatively small for faster system response.

With reference to FIG. 6, one example of a computer system is shown. The depicted system generally comprises a CPU 100 that is coupled to a power supply 606, a wireless interface 604, and memory 602. It is coupled to the power supply 606 (e.g., AC adaptor, battery) to receive from it power when in operation. It is coupled to the wireless interface 604 and to the memory 602 with separate point-to-point links to communicate with the respective components. The wireless interface 604 may comprise circuitry and one or more antennas to communicatively link the CPU 100 to a network such as a local network or a wide area network. The CPU 100 includes an error based supply regulator 105 (as discussed with reference to FIG. 1) with a CPU supply regulator 109 coupled to the power supply 606.

It should be noted that in a system with error correction, one should not equate “excessive errors” or “excessive error rate” with incorrect operation. Instead, these terms indicate that the probability of incorrect operation is no longer negligible, or may be approaching the point where the quality goals would be compromised.

It should be noted that often “soft errors” (those that occur only once) have little (if any) dependence on Vcc. Thus, any of the described circuits, methods, or systems can be enhanced by ignoring errors that only occur once.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), application specific integrated circuits (ASICs), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a CPU comprising:
a cache circuit having a plurality of memory cells, the cache circuit to provide an error signal indicative of cell errors from the cache;
a supply regulator circuit coupled to the cache circuit to supply it with power; and
an error processing circuit coupled to the supply regulator to control the power to be provided to the cache circuit based on the error signal.

2. The chip of claim 1, in which the error signal includes a bit error rate signal.

3. The chip of claim 1, in which the supply regulator circuit is to supply the cache with a voltage supply.

4. The chip of claim 1, in which the error processing circuit is coupled to the cache to receive the error signal.

5. The chip of claim 1, in which the error processing circuit is made to increment the power to be supplied if the error signal indicates that excessive errors are occurring.

6. The chip of claim 5, in which the error processing circuit is made to increment the power to be supplied if the error signal indicates that bits are being corrected at an excessive rate.

7. The chip of claim 1, in which the CPU comprises an error log coupled to the cache to receive the error signal and to the error processing circuit to provide it with a count of unique, corrected cells.

8. A method, comprising:
monitoring error information from a cache associated with a CPU; and
controlling a supply level to the CPU based on the monitored error information.

9. The method of claim 8, in which the supply level comprises a supply voltage.

10. The method of claim 8, in which the error information comprises bit error rate information.

11. The method of claim 10, in which the act of controlling the supply level includes increasing the supply level if the error information indicates an excess error rate.

12. The method of claim 11, in which the act of controlling the supply level includes decreasing the supply level if the error information indicates an insufficient error rate.

13. The method of claim 8, in which the error information comprises a count of unique, errant bit locations.

14. The method of claim 8, in which the error information comprises a count of unique, recurring, errant bit locations.

15. A circuit, comprising:
a cache circuit having a plurality of memory cells, the cache circuit to provide an error signal indicating a location of an errant bit;
a supply regulator circuit coupled to the cache circuit to supply it with power;
an error processing circuit coupled to the supply regulator to control the power to be supplied to the cache circuit; and
an error log circuit coupled to the cache to receive the error signal and to the error processing circuit to provide it with a count of unique errant bit locations, the error processing circuit to control the power to be supplied to the cache based on the count.

16. The circuit of claim 15, in which the supply regulator circuit is to supply the cache with a voltage supply.

17. The circuit of claim 15, in which the error processing circuit is made to check the count after waiting for a predefined amount of time.

18. The circuit of claim 17, in which the power to be supplied is a dynamic voltage supply with an associated minimum guardband level, wherein the error processing circuit increments said guardband level if the count is excessive.

19. The circuit of claim 15, in which errant bits refers to corrected bits.

20. The circuit of claim 19, in which corrected bit locations are only logged once they have failed more than once

21. A computer system, comprising:
(a) a CPU comprising a cache circuit having a plurality of memory cells, the cache circuit to provide an error signal indicative of cell errors from the cache, a supply regulator circuit coupled to the cache circuit to supply it with power, and an error processing circuit coupled to the supply regulator to control the power to be provided to the cache circuit based on the error signal; and
(b) a wireless interface, including an antenna, coupled to the microprocessor to communicatively link the CPU to a network.

22. The system of claim 21, comprising a battery coupled to the supply regulator to provide it with power when the CPU is to be operated.

23. The system of claim 21, in which the CPU comprises an error log coupled to the cache to receive the error signal and to the error processing circuit to provide it with a count of unique, corrected cells.

24. The system of claim 21, in which the CPU comprises an error log coupled to the cache to receive the error signal and to the error processing circuit to provide it with a count of unique, locations that have been corrected multiple times.
